(19) United States
(12) Patent Application Publication
(10) Pub. No.: US 2011/0130008 A1
(43) Pub. Date: Jun. 2, 2011

(54) METHOD TO CONTROL CRITICAL DIMENSION

(76) Inventors: Ming-Da Hsieh, Kaohsiung City (TW); Yu-Tsung Lai, Tai-Chung Hsien (TW); Jyh-Cherng Yau, Tai-Nan City (TW); Jiunn-Hsiung Liao, Tainan Hsien (TW)

(21) Appl. No.: 12/629,031

(22) Filed: Dec. 1, 2009

(51) Int. Cl. H01L 21/306

(52) U.S. Cl. 438/735; 257/E21.215

(57) ABSTRACT

A method to control a critical dimension is disclosed. First, a material layer and a composite patterned layer covering the material layer are provided. The composite patterned layer has a pattern defining a first critical dimension. Later, an etching gas is used to perform an etching step to etch the composite patterned layer and a pattern-transferring step is carried out so that thereby the underlying material layer has a transferred pattern with a second critical dimension which is substantially smaller than the first critical dimension.

### BACKGROUND OF THE INVENTION

1. Field of the Invention

The present invention relates to a method for controlling a critical dimension. In particular, the present invention relates to a method for controlling a post critical-dimension by employing a special etching gas recipe.

2. Description of the Prior Art

A lithographic process is one of the most key steps in the entire semiconductor process because an excellent lithographic process not only may positively influence the integration as well the performance of elements but also positively influences the through output as well as the production cost. Accordingly, the lithographic process device becomes a mainstream technology of the most advanced pattern transfer technique due to its very high throughput.

A basic lithographic process includes steps such as spin coating, soft baking, exposure, post exposure baking, development and hard baking . . . etc. In order to accurately transfer a pattern which is defined by the photoresist, a current method is known to use a composite photoresist layer.

FIG. 1-FIG. 3 illustrate a conventional method which uses a composite photoresist layer to transfer a pattern which is defined by the photoresist in the prior art. Please refer to FIG. 1. For example, a photoresist layer 110 on the substrate 101 has a bi-layer structure, respectively called a BARC layer 111 and a photoresist 112. The photoresist 112 has undergone proper exposure and development procedures to have a pre-determined photoresist pattern 114. The photoresist pattern 114 has a specific critical dimension.

Theoretically speaking, the critical dimension is not only affected by the parameters of the photolithographic step, but the parameters of the etching step also influence the critical dimension of the later transferred pattern (not shown). Accordingly, regarding the critical dimension bias (CD bias), i.e. for a fixed after development inspect critical dimension (ADICD), different parameters of the etching step make different after etch inspect critical dimensions (AEICD). In other words, for a fixed after development inspect critical dimension (ADICD), different parameters of the etching step may keep the after etch inspect critical dimensions (AEICD) unchanged, as shown in FIG. 2, or make the after etch inspect critical dimensions (AEICD) adversely enlarged, as shown in FIG. 3. Such changed CD bias represents that the etching step does not pass the critical dimension of the pre-determined photoresist correctly, and eventually, the critical dimension of the final semiconductor elements is too large to meet the original specification.

In view of this, a novel method for controlling a critical dimension is stilled needed to shrink the critical dimension bias (CD bias) after development and after etch, i.e. the difference of the after development inspect critical dimension (ADICD) and the after etch inspect critical dimension (AEICD) as small as possible keep the critical dimension of a lithographic process correct as much as possible.

### SUMMARY OF THE INVENTION

The present invention therefore proposes a novel method for controlling a critical dimension. The results of the method of the present invention may make the after etch inspect critical dimension (AEICD) not larger than the after development inspect critical dimension (ADICD) so as to keep the critical dimension of a lithographic process correct as much as possible.

A method to control a critical dimension is proposed. First, a material layer is provided. Second, a composite patterned layer is provided. The composite patterned layer covers the material layer and has a pattern which defines a first critical dimension. Later, an etchant is used to perform an etching step to etch the composite patterned layer and a pattern-transferring step is carried out thereby the material layer with a transferred pattern with a second critical dimension can be formed. The etchant includes carbon dioxide. The method to control a critical dimension of the present invention is characterized in that the second critical dimension is substantially smaller than the first critical dimension.

The present invention further proposes a method to control a critical dimension in a dual-damascene structure. First, a multi-material layer and a hard mask layer disposed on the multi-material layer are provided. Second, a composite patterned layer is provided. The composite patterned layer is disposed on the hard mask layer and has a pattern which defines a first critical dimension. Later, an etchant is used to perform an etching step to etch the composite patterned layer and a pattern-transferring step is carried out thereby the multi-material layer having a via structure with a second critical dimension for use in a dual-damascene structure can be formed. The etchant includes carbon dioxide. The method to control a critical dimension in a dual-damascene structure of the present invention is characterized in that the second critical dimension is substantially smaller than the first critical dimension.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1-FIG. 3 illustrate a conventional method which uses a composite photoresist layer to transfer pattern which is defined by the photoresist in the prior art.

FIG. 4A-FIG. 6 illustrate the method for use in gate to control a critical dimension of the present invention.

FIG. 7-FIG. 12 illustrate the method to control a critical dimension in a dual-damascene structure of the present invention.

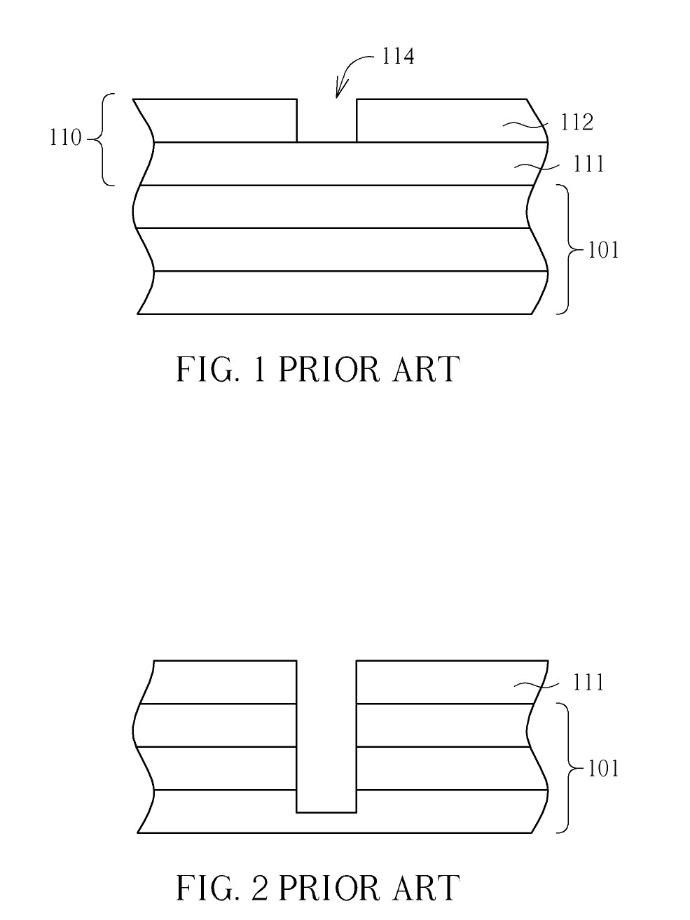

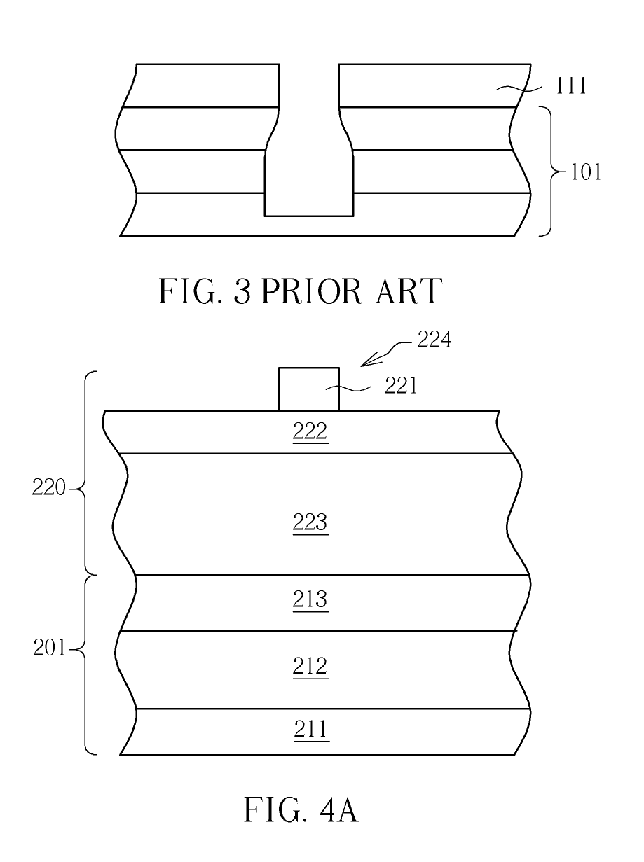

### DETAILED DESCRIPTION

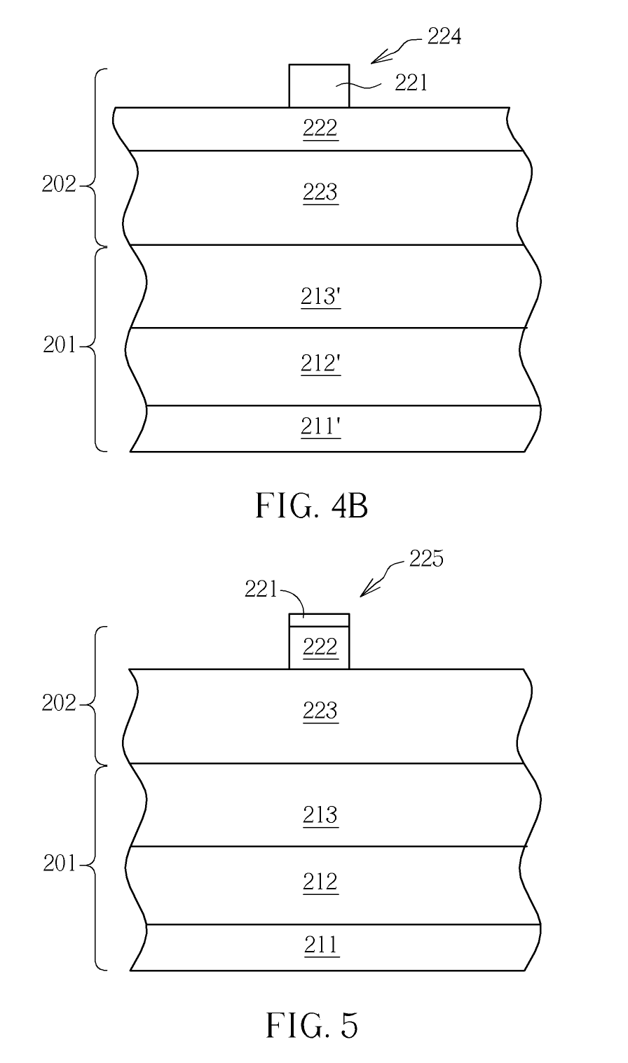

The present invention provides a method to control a critical dimension. The method of the present invention is useful in controlling the critical dimension of single damascene structure, dual damascene structure and trenches in shallow trench isolation. One feature of the present invention resides in that a composite patterned layer including a silicon-containing hard-mask anti-reflection coating layer which is sandwiched between two photoresist layers is used to define patterns of the material layer or openings in the material layer. Carbon dioxide is used as an etchant to define the composite patterned layer. FIG. 4A-FIG. 6 illustrate the method for use in gate to control a critical dimension of the present invention. First, as shown in FIG. 4A, a material layer 201, such as a gate material layer, and a composite patterned layer 202 are provided. The material layer 201 may include various materials for use in the formation of gates. When for use in poly-Si gates, as shown in FIG. 4A, the material layer 201 may include a gate oxide layer 211, a gate poly-Si layer 212, and an optional hard mask layer 213. When for use in metal gates, as shown in FIG. 4B, the material layer 201 may include a high-k material layer 211′, such as a high-k material containing Hf, a work function metal layer 212′ for adjusting the work function of gates and disposed on the high-k material layer 211′, and a gate electrode layer 213′, which is disposed on the work function metal layer 212′ and may include conductive material, such as poly-Si and a corresponding hard mask.

Optionally, there may be a silicon oxide layer (not shown) disposed under the high-k material layer 211′. Alternatively, there may be a cap dielectric layer (not shown) disposed between the high-k material layer 211′ and the metal layer 212′.

The composite patterned layer 202 may include a positive photoresist or a negative photoresist, and a silicon-containing hard-mask bottom anti-reflection coating layer (SHB). For example, the composite patterned layer 202 may include a photoresist 221 which is sensitive to the deep UV light, such as a KrF photoresist, an anti-reflection coating layer 222 and an I-line photoresist layer 223. As known by persons of ordinary skills in the art, the anti-reflection coating layer 222 may be a single or multi-layer anti-reflection coating layers, such as a silicon-containing hard-mask anti-reflection coating layer (SHB), including an organosilicon polymer or a polysilane with at least one chromophore group and a crosslinkable group. The I-line photoresist layer is most sensitive to a wave of a wavelength 365 nm. Preferably, the photoresist 221 has been patterned to have a pre-determined layout pattern. FIG. 4A and FIG. 4B both illustrate the photoresist 221 have a pre-determined gate pattern 224.

The photoresist 221 in the composite patterned layer 202 may be used as an etching mask of the following etching step so a pattern 224 which defines a first critical dimension has been constructed. For example, steps such as spin coating, soft baking, exposure, post exposure baking, development and hard baking . . . etc. are used in combination with at least one of a scanner and a stepper to construct the photoresist 221 with a pattern 224 which defines a first critical dimension. Later, the pattern 224 which defines a first critical dimension is used to transfer a pre-determined gate pattern into an underlying material layer.

Next, as shown in FIG. 5, a first etching step is performed using the patterned photoresist 221 as an etching mask to transfer the pattern 224 with the first critical dimension into the underlying anti-reflection coating layer 222 to form a first transferred pattern 225 with the first critical dimension. If the anti-reflection coating layer 222 is an organosilicon polymer or a polysilane, a mixed gas containing trifluoromethane and tetrafluoromethane may be used as the etchant. On the other hand, the I-line photoresist layer 223 may be used as the etching-stop layer. Or alternatively, the I-line photoresist layer 223 may be optionally over-etched.

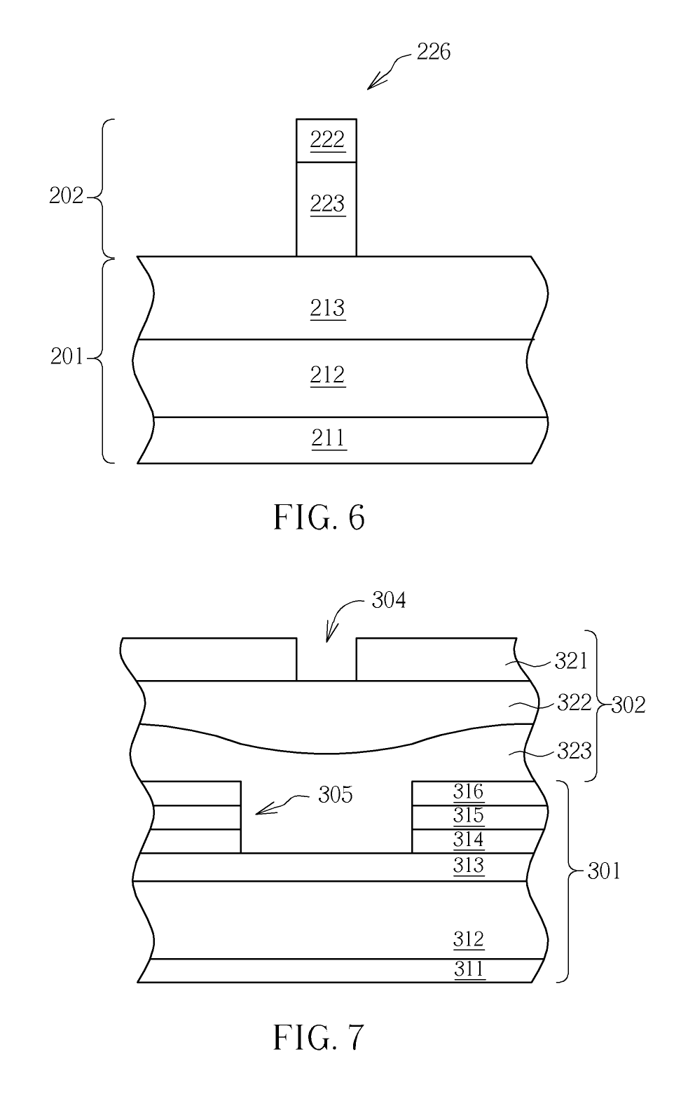

Afterwards, as shown in FIG. 6, the first transferred pattern 225 with the first critical dimension is used as the etching masks to carry out a second etching step to etch the I-line photoresist layer 223 to form a pattern 226. The second etching step may completely remove the photoresist 221. A specially formulated etchant may be used to carry out the second etching step so as to etch the I-line photoresist layer, and thereby a pattern 226 with a second critical dimension is formed. The etchant may be a gas such as carbon dioxide. Optionally, the etching gas of the present invention may further include an auxiliary gas, such as carbon monoxide.

After all the layers in the composite patterned layer 202 are defined, the remaining composite patterned layer 202 may be used as the etching mask to etching the hard mask layer 213 in the material layer 201 to continue defining the patterns. Later, optionally, different approaches may be employed. For example, the remaining composite patterned layer 202 and the patterned hard mask layer 213 may be used as the etching mask to etch the material layer 201 one or more times. Or, alternatively, an ashing procedure is first carried out to remove the remaining composite patterned layer 202 before the underlying material layer 201 is etched one or more times by using the patterned hard mask layer 213 as the etching mask.

After the second etching step of the present invention, a greatly reduced side-etching result is obtained in the I-line photoresist layer 223. It is believed that an adverse side-etching result would negatively influence the size of the critical dimension of the transferred pattern. In other words, a side-etching changes the critical dimension of the transferred pattern so a CD bias other than it is expected is obtained after a pattern of smaller critical dimension is transferred.

Compared with the conventional etching recipe which contains oxygen, the recipe of the present invention uses carbon dioxide to etch the I-line photoresist layer 223 and the undesirable side-etching result is effectively inhibited so that the after etch inspect critical dimension (AEICD) may be substantially similar to the after development inspect critical dimension (ADICD) to keep the critical dimension correctly passed as much as possible in a lithographic process. Then, the conventional etching procedures may be carried out to go on constructing the needed gate structure. Such techniques are well known so the details will not be described here. Given the above, one of the advantageous features of the present invention resides in that carbon dioxide used as the etching gas to etch the I-line photoresist layer 223 in fact effectively inhibits the undesirable side-etching result. This unexpected effect exhibits a result that the second critical dimension is substantially similar to the first critical dimension after the etching is completed.

On the other hand, the method to control a critical dimension of the present invention may also be used in controlling a critical dimension in a dual-damascene structure. One feature of the present invention resides in that a composite patterned layer including a silicon-containing hard-mask anti-reflection coating layer which is sandwiched between two photoresist layers is used to define the patterns of the material layer or the openings in the material layer 201. Carbon dioxide is used as etchant to define the composite patterned layer. In other words, the method of the present invention may also be used in a substrate to form the via structure in a dual-damascene structure or in a single-damascene structure. FIG. 7-FIG. 12 illustrate the method to control a critical dimension in a dual-damascene structure of the present invention. First, as shown in FIG. 7, a multi-material layer 301 and a composite patterned layer 302 are provided. The multi-material layer 301 may include various material layers, such as a hard mask layer 303, a pad oxide layer 311, an ultra low-k material (AULK) layer 312 and a tetraethoxysilane (TEOS)layer 313. The hard mask layer 303 may be a composite hard mask layer, which may include a TiN layer 314, a SiON layer 315 and a cap layer 316 . . . etc. The order of layers in the hard mask layer 303 is optional.

The composite patterned layer 302 may include a positive photoresist or a negative photoresist, a silicon-containing hard-mask bottom anti-reflection coating layer and one or more anti-reflection layers disposed on the silicon-containing hard-mask bottom anti-reflection coating layer. For example, the composite patterned layer 302 may include a photoresist 321 which is sensitive to the deep UV light, such as a KrF photoresist, an anti-reflection coating layer 322 and an I-line photoresist layer 323. The composite patterned layer 302 may optionally include one or more anti-reflection layers disposed on the silicon-containing hard-mask bottom anti-reflection coating layer, which all are represented by the illustration of the anti-reflection coating layer 322. As known by persons of ordinary skills in the art, the anti-reflection coating layer 322 may be a silicon-containing hard-mask anti-reflection coating layer (SHB), including an organosilicon polymer or a polysilane with at least one chromophore group and a crosslinkable group. The I-line photoresist layer is most sensitive to a wave of a wavelength 365 nm. Preferably, the photoresist 321 has been patterned to have a pre-determined layout pattern. FIG. 7 illustrates the photoresist 321 have a pre-determined via pattern 304 for use in a dual-damascene structure. On the other hand, the hard mask layer 303 may be pre-defined a trench pattern for use in the dual-damascene structure.

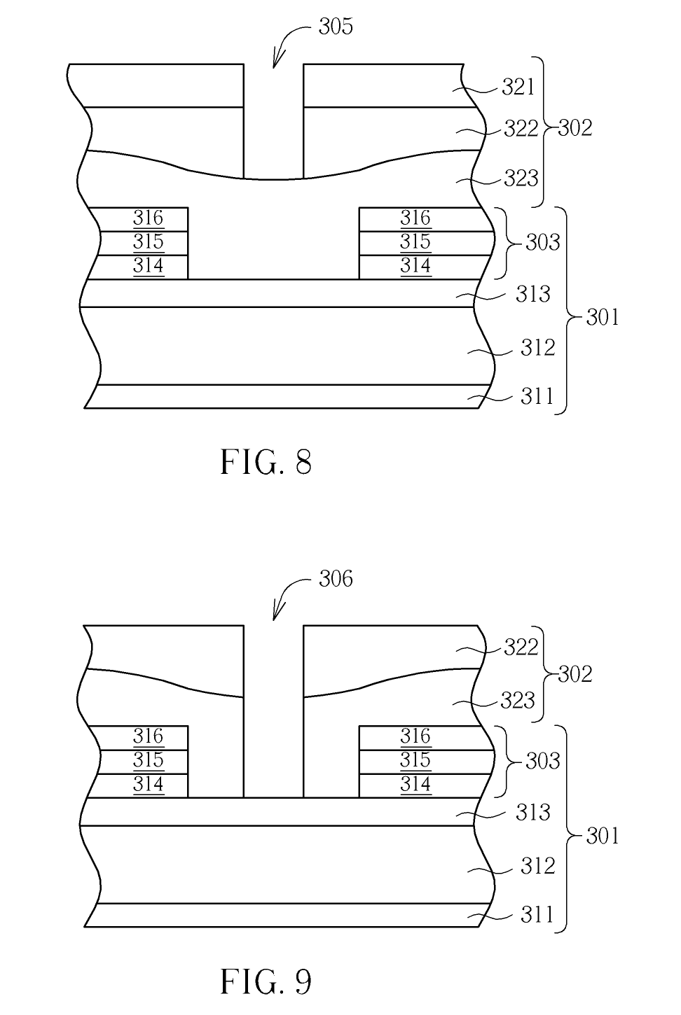

Later, as shown in FIG. 8, a first etching step is performed using the patterned photoresist 321 as an etching mask to transfer the pattern 304 with the first critical dimension into the underlying anti-reflection coating layer 322 to form a first transferred pattern 305 with the first critical dimension. If the anti-reflection coating layer 322 is an organosilicon polymer or a polysilane, a mixed gas containing trifluoromethane and tetrafluoromethane may be used as the etchant. On the other hand, the I-line photoresist layer 323 may be used as the etching-stop layer. Or alternatively, the I-line photoresist layer 323 may be optionally over-etched.

Afterwards, as shown in FIG. 9, the anti-reflection coating layer 322 having the first transferred pattern 305 with the first critical dimension is used as the etching mask to carry out a second etching step to etch the I-line photoresist layer 323 to form a pattern 306. The second etching step may completely remove the patterned photoresist 321. A specially formulated etchant may be used to carry out the second etching step so as to etch the I-line photoresist layer 323, and thereby a pattern 306 with a second critical dimension is formed. The etchant may be a gas such as carbon dioxide. Optionally, the etching gas of the present invention may further include an auxiliary gas, such as carbon monoxide.

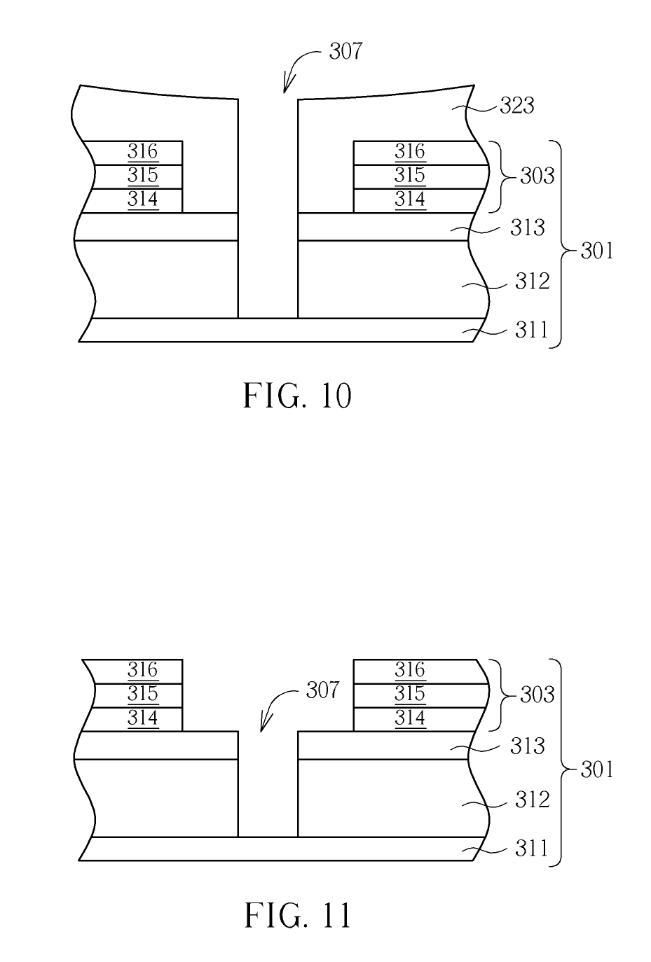

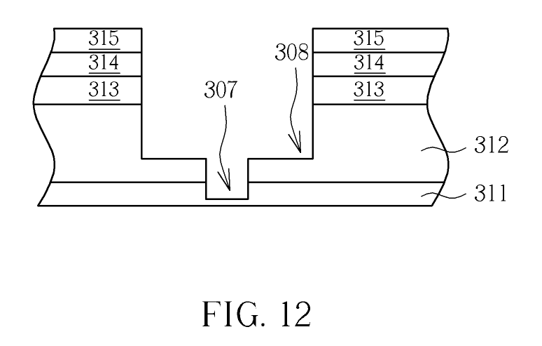

Thereafter, as shown in FIG. 10, a following etching step is carried out to again transfer the pattern 306 into the underlying tetraethoxysilane (TEOS) layer 313 and the ultra low-k material (AULK) layer 312 to form the via 307 in a dual-damascene structure. Next, an ashing procedure may be first carried out to remove I-line photoresist layer 323, as shown in FIG. 11, before the hard mask layer 303 which pre-defines the trench pattern for use in a dual-damascene structure is used as the etching mask to carry out another etching step to form a trench 308 in the dual-damascene structure in the tetraethoxysilane (TEOS) layer 313 and the ultra low-k material (AULK) layer 312, as well as to form the via 307 in the dual-damascene structure in the pad oxide layer 311, as shown in FIG. 12. Since the via 307 as well as the trench 308 are all constructed in the tetraethoxysilane (TEOS) layer 313 and the ultra low-k material (AULK) layer 312, the dual-damascene structure with the via 307 and with the trench 308 is therefore formed in the tetraethoxysilane (TEOS) layer 313 and the ultra low-k material (AULK) layer 312.

Because the present invention uses carbon dioxide as an etchant to avoid an adverse side-etching result when the I-line photoresist layer 323 is etched, the pattern 306 with the second critical dimension can be precisely controlled in the I-line photoresist layer 323. The via 307 in the dual-damascene structure of course has a critical dimension as expected.

Compared with the conventional etching recipe containing oxygen, the recipe of the present invention uses carbon dioxide to etch the I-line photoresist layer 323 and the undesirable side-etching result is effectively inhibited so that the after etch inspect critical dimension (AEICD) is not larger than the after development inspect critical dimension (ADICD) to keep the critical dimension correctly passed as much as possible in a lithographic process. Given the above, one of the features of the present invention resides in that carbon dioxide used as the etching gas to etch the I-line photoresist layer 323 effectively inhibits the undesirable side-etching result. This unexpected effect exhibits a result that the second critical dimension is substantially smaller than the first critical dimension, i.e. the after etch inspect critical dimension (AEICD) is not larger than the after development inspect critical dimension (ADICD) after the etching is completed.

Those skilled in the art will readily observe that numerous modifications and alterations of the device and method may be made while retaining the teachings of the invention.

What is claimed is:

1. A method to control a critical dimension, comprising:
providing a material layer;
providing a composite patterned layer which covers said material layer, said composite patterned layer has a pattern which defines a first critical dimension (CD); and
using an etching gas to perform an etching step to etch said composite patterned layer so that said material layer having a transferred pattern with a second critical dimension is formed, wherein said etching gas comprises carbon dioxide and said second critical dimension is substantially similar to said first critical dimension.

2. The method to control a critical dimension of claim 1, wherein said composite patterned layer comprises a composite photoresist structure.

3. The method to control a critical dimension of claim 1, wherein said composite photoresist structure further sandwiches a silicon-containing hard-mask anti-reflection coating layer.

4. The method to control a critical dimension of claim 3, wherein said etching gas etches said I-line photoresist.

5. The method to control a critical dimension of claim 1, wherein a development step is performed to define said first critical dimension.

6. The method to control a critical dimension of claim 1, wherein said etching gas further comprises carbon monoxide.

7. The method to control a critical dimension of claim 1, wherein said etching gas further comprises an auxiliary gas.

8. The method to control a critical dimension of claim 1, wherein said composite patterned layer comprises an organic material.

9. The method to control a critical dimension of claim 1, wherein at least one of a scanner and a stepper is used to define said pattern.

10. A method to control a critical dimension in a dual-damascene structure, comprising:
providing a multi-material layer;
providing a hard mask layer disposed on said multi-material layer and defining a trench dimension in a dual-damascene structure;
providing a composite patterned layer disposed on said hard mask layer and having a pattern which defines a first critical dimension; and
using an etching gas to perform an etching step to etch said composite patterned layer so that said multi-material layer forms a via with a second critical dimension for use in said dual-damascene structure, wherein said etching gas comprises carbon dioxide and said second critical dimension is substantially smaller than said first critical dimension.

11. The method to control a critical dimension in a dual-damascene structure of claim 10, wherein said composite patterned layer comprises a composite photoresist structure.

12. The method to control a critical dimension in a dual-damascene structure of claim 10, wherein said composite photoresist structure comprises a photoresist layer and an I-line photoresist.

13. The method to control a critical dimension in a dual-damascene structure of claim 12, wherein said etching gas etches said I-line photoresist.

14. The method to control a critical dimension in a dual-damascene structure of claim 10, wherein a development step is performed to define said first critical dimension.

15. The method to control a critical dimension in a dual-damascene structure of claim 10, wherein said etching gas further comprises carbon monoxide.

16. The method to control a critical dimension in a dual-damascene structure of claim 10, wherein said etching gas further comprises an auxiliary gas.

17. The method to control a critical dimension in a dual-damascene structure of claim 10, wherein said composite patterned layer comprises an organic material.

18. The method to control a critical dimension in a dual-damascene structure of claim 10, wherein at least one of a scanner and a stepper is used to define said pattern.

19. The method to control a critical dimension in a dual-damascene structure of claim 10, further comprising:
constructing a trench in said multi-material layer so that said trench and said via together form said dual-damascene structure.

20. The method to control a critical dimension in a dual-damascene structure of claim 12, wherein said photoresist layer and said I-line photoresist further sandwiches a silicon-containing hard-mask anti-reflection coating layer.
